(19) United States
(12) Patent Application Publication
(10) Pub. No.: US 2025/0171901 A1
(43) Pub. Date: May 29, 2025

(54) ELECTROSTATIC CHUCK APPARATUS

(71) Applicant: SAMSUNG ELECTRONICS CO., LTD., SUWON-SI (KR)

(72) Inventors: Dongsu KIM, Suwon-si (KR); Sungyeol KIM, Suwon-si (KR); Sungyoung YOON, Suwon-si (KR); Meehyun LIM, Suwon-si (KR); Jaehyun CHOI, Suwon-si (KR); Minsung KIM, Suwon-si (KR); Jeonghyoun SUNG, Suwon-si (KR); Sangyeon OH, Suwon-si (KR); Sanghoon JUNG, Suwon-si (KR)

(21) Appl. No.: 18/949,062

(22) Filed: Nov. 15, 2024

(30) Foreign Application Priority Data
Nov. 24, 2023 (KR) 10-2023-0165828

(51) Int. Cl. C23C 16/458

(52) U.S. Cl. CPC C23C 16/4586

(57) ABSTRACT

An electrostatic chuck apparatus includes: a chuck plate configured to support a wafer; a shaft extending from a bottom surface of the chuck plate in a vertical direction and configured to support the chuck plate; an inner electrode disposed inside the chuck plate and having a disc shape in a central portion of the chuck plate; and a plurality of outer electrodes disposed inside the chuck plate and adjacent to the inner electrode in a radial direction of the chuck plate, wherein the plurality of outer electrodes include a first outer electrode including: a first side portion having a cylindrical shape and extending in the vertical direction; a first top portion having a planar annular shape and connected to an upper end of the first side portion; and a first bottom portion having a planar annular shape and connected to a lower end of the first side portion.

### CROSS-REFERENCE TO RELATED APPLICATION

This application claims priority under 35 U.S.C. § 119 to Korean Patent Application No. 10-2023-0165828, filed on Nov. 24, 2023, in the Korean Intellectual Property Office, the disclosure of which is incorporated by reference herein in its entirety.

### TECHNICAL FIELD

Embodiments of the present inventive concept relate to a semiconductor processing apparatus, and more particularly, to an electrostatic chuck apparatus arranged in a processing chamber that is used in semiconductor manufacturing processes.

### DISCUSSION OF THE RELATED ART

Semiconductor devices or display devices are manufactured by sequentially stacking multiple thin layers, which include a dielectric layer and a metal layer, on a substrate and patterning the multiple thin layers. For example, these thin layers may be sequentially vapor-deposited on the substrate through chemical vapor deposition (CVD) or physical vapor deposition (PVD). Generally, a CVD apparatus and a PVD apparatus may each include a heater. In addition, an electrode, which applies a chucking force for holding the substrate, may be provided in a plate of a chuck apparatus.

### SUMMARY

According to an embodiment of the present inventive concept, an electrostatic chuck apparatus includes: a chuck plate configured to support a wafer; a shaft extending from a bottom surface of the chuck plate in a vertical direction and configured to support the chuck plate; an inner electrode disposed inside the chuck plate and having a disc shape in a central portion of the chuck plate; and a plurality of outer electrodes disposed inside the chuck plate and adjacent to the inner electrode in a radial direction of the chuck plate, wherein the plurality of outer electrodes include a first outer electrode including: a first side portion having a cylindrical shape and extending in the vertical direction; a first top portion having a planar annular shape and connected to an upper end of the first side portion; and a first bottom portion having a planar annular shape and connected to a lower end of the first side portion.

According to an embodiment of the present inventive concept, an electrostatic chuck apparatus includes: a chuck plate including a top surface that includes a wafer supporting surface and a circumferential surface, wherein a wafer is mounted on the wafer supporting surface, and wherein the circumferential surface is around an outer edge of the wafer supporting surface and forms a step with the wafer supporting surface; a shaft extending from a bottom surface of the chuck plate in a vertical direction and configured to support the chuck plate; an inner electrode disposed inside the chuck plate and having a disc shape in a central portion of the chuck plate; a first outer electrode disposed inside the chuck plate and including a first side portion, a first top portion, and a first bottom portion, wherein the first side portion has a cylindrical shape and extends in the vertical direction, wherein the first top portion has a planar annular shape that is connected to an upper end of the first side portion and that is arranged adjacent to the inner electrode in a radial direction of the chuck plate, wherein the first top portion is disposed at substantially a same vertical level as the inner electrode and overlaps the wafer supporting surface in the vertical direction, wherein the first bottom portion has a planar annular shape that is connected to a lower end of the first side portion, and wherein the first bottom portion has an inner diameter that is less than an inner diameter of the first top portion; a second outer electrode disposed inside the chuck plate and including a second side portion, a second top portion, and a second bottom portion, wherein the second side portion has a cylindrical shape and extends in the vertical direction, wherein the second top portion has a planar annular shape that is connected to an upper end of the second side portion and that is arranged adjacent to the first top portion of the first outer electrode in the radial direction of the chuck plate, wherein the second top portion is disposed at substantially the same vertical level as the inner electrode and at least partially overlaps the wafer supporting surface in the vertical direction, wherein the second bottom portion has a planar annular shape that is connected to a lower end of the second side portion, and wherein the second bottom portion has an inner diameter that is less than an inner diameter of the second top portion; an inner conductive wire connected to the inner electrode; a first outer conductive wire connected to the first bottom portion of the first outer electrode; a second outer conductive wire connected to the second bottom portion of the second outer electrode; and a heater electrode overlapping the inner electrode, the first outer electrode, and the second outer electrode, wherein the second bottom portion of the second outer electrode is disposed below the first bottom portion of the first outer electrode, wherein an inner diameter of the second bottom portion of the second outer electrode is greater than an inner diameter of the first bottom portion of the first outer electrode, and wherein the inner conductive wire, the first outer conductive wire, and the second outer conductive wire are each connected to a direct current (DC) power supply and an impedance control module.

According to an embodiment of the present inventive concept, an electrostatic chuck apparatus includes: a chuck plate configured to support a wafer; a shaft extending from a bottom surface of the chuck plate in a vertical direction and configured to support the chuck plate; an inner electrode disposed inside the chuck plate and having a disc shape in a central portion of the chuck plate; and a plurality of outer electrodes disposed inside the chuck plate and adjacent to the inner electrode in a radial direction of the chuck plate, wherein the plurality of outer electrodes includes a first outer electrode including: a first side portion having a cylindrical shape and extending in the vertical direction; a first top portion having a planar annular shape; a first upper round portion connecting the first top portion to a top end of the first side portion; a first bottom portion having a planar annular shape; and a first lower round portion connecting the first bottom portion to a bottom end of the first side portion.

### BRIEF DESCRIPTION OF THE DRAWINGS

The above and other aspects of the present inventive concept will become more apparent by describing in detail embodiments thereof, with reference to the accompanying drawings, in which:

FIG. 1 is a schematic perspective view of a plasma generator according to an embodiment of the present inventive concept;

FIG. 2 is a cross-sectional view of an electrostatic chuck apparatus according to an embodiment of the present inventive concept;

FIG. 3 is a schematic perspective view illustrating an internal arrangement of an electrostatic chuck apparatus, according to an embodiment of the present inventive concept;

FIG. 4 is a functional block diagram of a controller according to an embodiment of the present inventive concept;

FIG. 5 is a cross-sectional view of an electrostatic chuck apparatus according to an embodiment of the present inventive concept; and

FIG. 6 is a cross-sectional view of an electrostatic chuck apparatus according to an embodiment of the present inventive concept.

### DETAILED DESCRIPTION OF THE EMBODIMENTS

Hereinafter, embodiments of the present inventive concept are described in detail with reference to the accompanying drawings. In the drawings and specification, like reference characters and numerals may denote like elements, and any redundant descriptions thereof may be omitted or briefly discussed. It is also noted that, as used herein, the terms “substantially,” “about,” and other similar terms, are used as terms of approximation, not as terms of degree, and thus are utilized to account for inherent deviations in measured, calculated, and/or provided values that would be recognized by one of ordinary skill in the art.

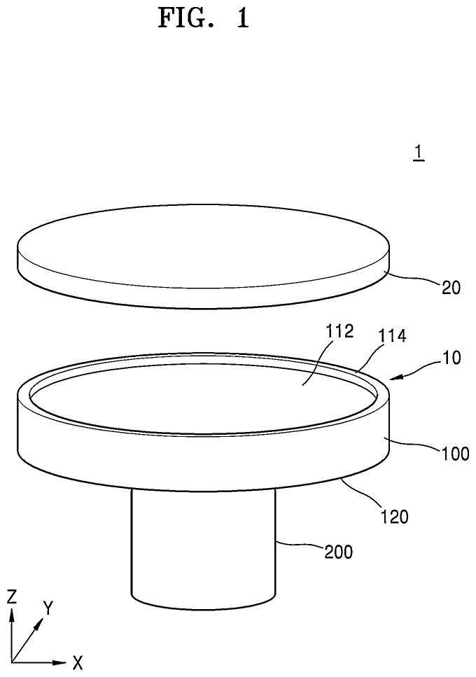

FIG. 1 is a schematic perspective view of a plasma generator 1 according to an embodiment of the present inventive concept.

Referring to FIG. 1, the plasma generator 1 may include an electrostatic chuck apparatus 10 and a shower head 20.

The electrostatic chuck apparatus 10 may be used to support and heat a wafer during chemical vapor deposition (CVD) by using plasma and may be attached inside a semiconductor process chamber.

The shower head 20 may be separated from the electrostatic chuck apparatus 10 in a vertical direction (a Z direction). The shower head 20 may spray a process gas on a surface of a wafer located in the electrostatic chuck apparatus 10 and apply power for generating plasma. The shower head 20 may be connected to a matcher and a power source, which stably maintain generation of plasma.

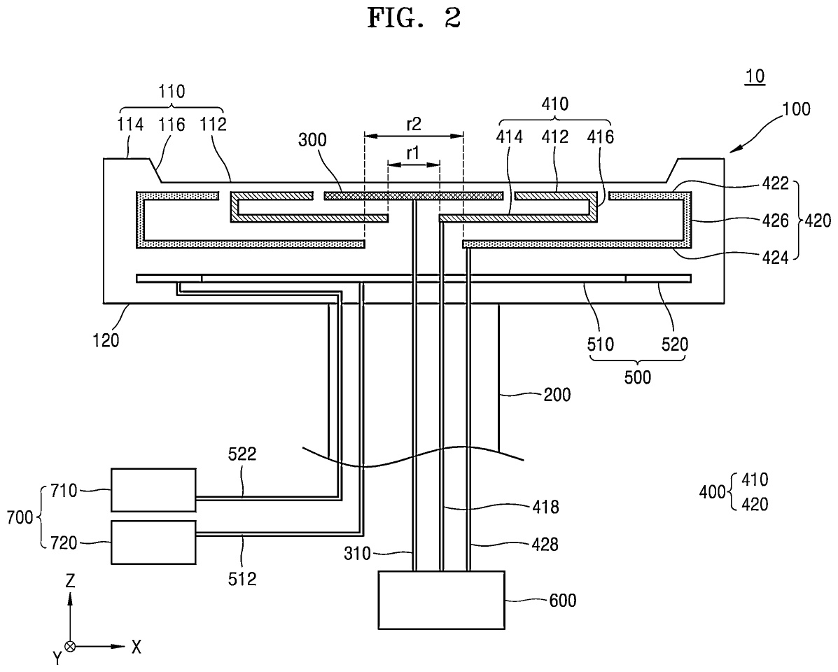

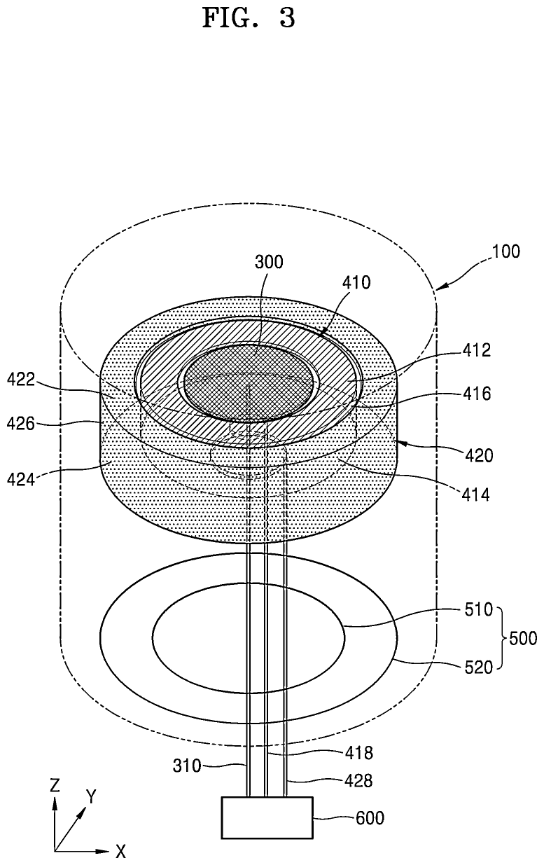

FIG. 2 is a cross-sectional view of the electrostatic chuck apparatus 10 according to an embodiment of the present inventive concept. FIG. 3 is a schematic perspective view showing an internal arrangement of the electrostatic chuck apparatus 10, according to an embodiment of the present inventive concept.

Referring to FIGS. 1 to 3, the electrostatic chuck apparatus 10 may include a chuck plate 100, a shaft 200, an inner electrode 300, a plurality of outer electrodes 400, a heater electrode 500, a controller 600, and a temperature controller 700.

The chuck plate 100 may have a disc shape or cylindrical shape and include a top surface 110 and a bottom surface 120 opposite to the top surface 110. For example, the chuck plate 100 may have a disk shape with the top surface 110 and the bottom surface 120, which are parallel with the horizontal direction (an X direction and/or a Y direction). The inner electrode 300, the outer electrodes 400, and the heater electrode 500 may be arranged inside the chuck plate 100. The top surface 110 of the chuck plate 100 may include a wafer supporting surface 112, on which a wafer is mounted, and a circumferential surface 114 forming a step with the wafer supporting surface 112. For example, the wafer supporting surface 112 may be disposed at a level that is different from the level at which the circumferential surface 114 is disposed. The circumferential surface 114 may be connected to the wafer supporting surface 112 through an inclined surface 116.

The shaft 200 may have a hollow cylindrical shape and may be arranged at the center of the bottom surface 120 of the chuck plate 100 to support the chuck plate 100. The shaft 200 may extend from the bottom surface 120 of the chuck plate 100 in the vertical direction (the Z direction). The shaft 200 may be bonded to the bottom surface 120 of the chuck plate 100 through diffusion bonding or thermal compression bonding (TCB).

An inner conductive wire 310, a first outer conductive wire 418, a second outer conductive wire 428, an inner coiled conductive wire 512, and an outer coiled conductive wire 522, which are described below, may be arranged in the shaft 200.

The electrostatic chuck apparatus 10 may include a material including aluminum nitride (AlN) to carry out a process at high temperature. However, the material of the electrostatic chuck apparatus 10 is not limited thereto and the electrostatic chuck apparatus 10 may include a material capable of ensuring sinterability under high temperatures. In an embodiment of the present inventive concept, the chuck plate 100 may supply heat to a wafer while chucking the wafer during CVD performed at a high temperature of about 600 degrees Celsius or higher.

The inner electrode 300 and the outer electrodes 400 may be arranged inside the chuck plate 100. According to an embodiment of the present inventive concept, the inner electrode 300 and the outer electrodes 400 may be embedded in the chuck plate 100 and may provide a chucking force for fixing a wafer to the wafer supporting surface 112.

The inner electrode 300 may have a disc shape or a cylindrical shape and may be located in a central portion of the chuck plate 100. For example, the inner electrode 300 may have a disc shape that is concentric to the chuck plate 100 and may be arranged such that a center of the chuck plate 100 in the radial direction thereof coincides with a center of the inner electrode 300 in the radial direction thereof. The inner electrode 300 may be arranged in the chuck plate 100 and may be arranged adjacent to the top surface 110 of the chuck plate 100 in the vertical direction (the Z direction).

For example, the inner electrode 300 may include a mesh electrode. In other words, the inner electrode 300 may be formed as a disc-shaped mesh. However, the inner electrode 300 is not limited thereto and may be formed as a sheet-shaped electrode.

The inner conductive wire 310 may be connected to the bottom surface of the inner electrode 300. The inner conductive wire 310 may connect the inner electrode 300 to the controller 600. The inner conductive wire 310 may penetrate through the chuck plate 100 and extend in the inner space of the shaft 200. The inner conductive wire 310 may be connected to the inner electrode 300 through an electrode terminal.

The outer electrodes 400 may be located outside the inner electrode 300 in the radial direction of the chuck plate 100. The outer electrodes 400 may have different sizes from each other. Each of the outer electrodes 400 may have a three-dimensional (3D) structure. Each 3D structure includes a top portion, which has a planar annular shape, and a bottom portion, which has a planar annular shape, and the planar annular shape of the top portion has an inner diameter that is different from an inner diameter of the planar annular shape of the bottom portion. For example, an inner diameter may correspond to a diameter of an opening (or, e.g., an inner circle) of a planar annular shape, and an outer diameter of a planar annular shape may refer to a diameter of an outer circle of the planar annular shape. In addition, each the 3D structure may include a side portion that connects the top portion and bottom portion to each other and that has a cylindrical shape.

According to an embodiment of the present inventive concept, the outer electrodes 400 may include a first outer electrode 410 and a second outer electrode 420.

The first outer electrode 410 may include a first top portion 412, a first bottom portion 414, and a first side portion 416.

The first top portion 412 may have a planar annular shape and may be located outside the inner electrode 300 in the radial direction of the chuck plate 100. For example, the first top portion 412 may be adjacent to the inner electrode 300. For example, the inner electrode 300 may be disposed in an opening of the first top portion 412. The inner diameter of the first top portion 412 may be greater than the diameter of the inner electrode 300. For example, the diameter of an opening of the top portion 412 may be larger than the diameter of the inner electrode 300. The first top portion 412 may be concentric to the inner electrode 300 and may be separated from the inner electrode 300 in the radial direction of the chuck plate 100.

The first bottom portion 414 may have a planar annular shape and may be located inside the chuck plate 100. The first bottom portion 414 may be separated from the first top portion 412 in the vertical direction (the Z direction). According to an embodiment of the present inventive concept, the outer diameter of the first bottom portion 414 may be the same as the outer diameter of the first top portion 412, and the inner diameter of the first bottom portion 414 may be less than the inner diameter of the first top portion 412.

The first side portion 416 may have a cylindrical shape and may connect the first top portion 412 to the first bottom portion 414. In other words, the top outer circumference of the first side portion 416 may be connected to the outer circumference of the first top portion 412, and the bottom outer circumference of the first side portion 416 may be connected to the outer circumference of the first bottom portion 414.

The first outer conductive wire 418 may be connected to the first bottom portion 414. The first outer conductive wire 418 may connect the first outer electrode 410 to the controller 600. The first outer conductive wire 418 may penetrate through the chuck plate 100 and extend in the inner space of the shaft 200. The first outer conductive wire 418 may be connected to the first outer electrode 410 through an electrode terminal.

The second outer electrode 420 may include a second top portion 422, a second bottom portion 424, and a second side portion 426. The shape of the second outer electrode 420 may be similar to the shape of the first outer electrode 410. The second top portion 422, the second bottom portion 424, and the second side portion 426 may respectively correspond to the first top portion 412, the first bottom portion 414, and the first side portion 416.

The second top portion 422 may have a planar annular shape and may be located outside the first top portion 412 in the radial direction of the chuck plate 100. For example, the second top portion 422 may be adjacent to the first top portion 412. The second top portion 422 may be located in the chuck plate 100 to be adjacent to the top surface 110 of the chuck plate 100 in the vertical direction (the Z direction). The inner diameter of the second top portion 422 may be greater than the outer diameter of the first top portion 412. The second top portion 422 may be concentric to the first top portion 412 and may be separated from the first top portion 412 in the radial direction of the chuck plate 100.

The second bottom portion 424 may have a planar annular shape and may be located inside the chuck plate 100. The second bottom portion 424 may be separated from the second top portion 422 in the vertical direction (the Z direction). According to an embodiment of the present inventive concept, the outer diameter of the second bottom portion 424 may be the same as the outer diameter of the second top portion 422 and the inner diameter of the second bottom portion 424 may be less than the inner diameter of the second top portion 422.

The second side portion 426 may have a cylindrical shape and may connect the second top portion 422 to the second bottom portion 424. In other words, the top outer circumference of the second side portion 426 may be connected to the outer circumference of the second top portion 422, and the bottom outer circumference of the second side portion 426 may be connected to the outer circumference of the second bottom portion 424.

The second outer conductive wire 428 may be connected to the second bottom portion 424. The second outer conductive wire 428 may connect the second outer electrode 420 to the controller 600. The second outer conductive wire 428 may penetrate through the chuck plate 100 and extend in the inner space of the shaft 200. The second outer conductive wire 428 may be connected to the second outer electrode 420 through an electrode terminal.

Each of the outer electrodes 400 may include a mesh electrode. However, each of the outer electrodes 400 is not limited thereto and may include a sheet electrode.

Each of the outer electrodes 400 may be integrally formed by bending a single mesh or sheet electrode. For example, the first top portion 412, the first side portion 416, and the first bottom portion 414 of the first outer electrode 410 may be connected to each other into one body. The second top portion 422, the second side portion 426, and the second bottom portion 424 of the second outer electrode 420 may be connected to each other into one body.

According to an embodiment of the present inventive concept, the top portion, the bottom portion, and the side portion of each of the outer electrodes 400 may be bonded to each other. For example, planar annular top and bottom portions may be bonded to a cylindrical side portion, thereby forming an outer electrode 400. The first outer electrode 410 may be formed by bonding the first top portion 412 to the top end of the first side portion 416 and bonding the first bottom portion 414 to the bottom end of the first side portion 416. The second outer electrode 420 may be formed by bonding the second top portion 422 to the top end of the second side portion 426 and bonding the second bottom portion 424 to the bottom end of the second side portion 426.

The relative arrangement of the inner electrode 300, the first outer electrode 410, and the second outer electrode 420 is described below.

The inner electrode 300, the first outer electrode 410, and the second outer electrode 420 may be arranged such that the central axes of the inner electrode 300, the first outer electrode 410, and the second outer electrode 420 coincide with one another. The inner electrode 300, the first outer electrode 410, and the second outer electrode 420 may be sequentially arranged in the radial direction outward from a center of the chuck plate 100. For example, the first outer electrode 410 may be arranged to surround the side and the bottom of the inner electrode 300, and the second outer electrode 420 may be arranged to surround the side and the bottom of the first outer electrode 410.

For example, the first outer electrode 410 and the second outer electrode 420 may be arranged such that the first top portion 412 and the second top portion 422 are at substantially the same vertical level as the inner electrode 300. For example, the first top portion 412, the second top portion 422, and the inner electrode 300 may be at substantially the same vertical level and may be parallel with the wafer supporting surface 112. According to an embodiment of the present inventive concept, the inner electrode 300 having a disc shape and the first top portion 412 having a planar annular shape may overlap the wafer supporting surface 112 in the vertical direction (the Z direction). The second top portion 422, which has a planar annular shape and is located outermost, with respect to the inner electrode 300 and the first top portion 412, in the radial direction of the chuck plate 100, may at least partially overlap the wafer supporting surface 112 in the vertical direction (the Z direction). Accordingly, the inner electrode 300, the first top portion 412 of the first outer electrode 410, and the second top portion 422 of the second outer electrode 420 may apply a chucking force to a wafer that is mounted on the wafer supporting surface 112.

The second bottom portion 424 of the second outer electrode 420 may be below the first bottom portion 414 of the first outer electrode 410. An inner diameter r2 of the second bottom portion 424 may be greater than an inner diameter r1 of the first bottom portion 414. As described above, the first outer conductive wire 418, which connects the first outer electrode 410 to the controller 600, may be connected to a side of the first bottom portion 414. The second outer conductive wire 428, which connects the second outer electrode 420 to the controller 600, may be connected to a side of the second bottom portion 424. As the inner diameter r2 of the second bottom portion 424 is greater than the inner diameter r1 of the first bottom portion 414, the first outer conductive wire 418 and the second outer conductive wire 428 may extend in one direction (the Z direction) without interfering with each other. For example, the first outer conductive wire 418 may be spaced apart from the second outer conductive wire 428.

The heater electrode 500 may be arranged below the inner electrode 300 and the outer electrodes 400. The heater electrode 500 may be inside the chuck plate 100 and separated from the inner electrode 300 and the outer electrodes 400 in the vertical direction (the Z direction). The heater electrode 500 may be parallel with the wafer supporting surface 112.

Although schematically shown in FIG. 3, the heater electrode 500 may include an inner coil 510 in a central portion thereof and an outer coil 520 outside the inner coil 510. The inner coil 510 and the outer coil 520 may be controlled to different temperatures to adjust the temperature of a wafer mounted on the wafer supporting surface 112 so that CVD may be carried out.

The controller 600 may be located outside the chuck plate 100 and the shaft 200. The controller 600 may control the impedance of the inner electrode 300 and the outer electrodes 400 and supply power to the inner electrode 300 and the outer electrodes 400.

The controller 600 may be connected to the inner electrode 300, the first outer electrode 410, and the second outer electrode 420 respectively through the inner conductive wire 310, the first outer conductive wire 418, and the second outer conductive wire 428. The controller 600 may control the impedance of each of the inner electrode 300, the first outer electrode 410, and the second outer electrode 420 respectively through the inner conductive wire 310, the first outer conductive wire 418, and the second outer conductive wire 428. The controller 600 may also provide power to the inner electrode 300, the first outer electrode 410, and the second outer electrode 420 respectively through the inner conductive wire 310, the first outer conductive wire 418, and the second outer conductive wire 428.

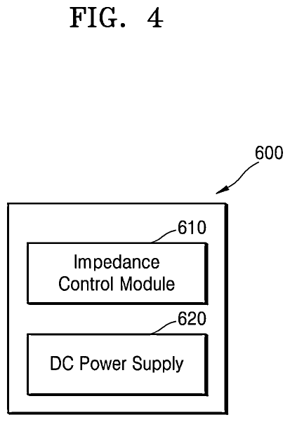

FIG. 4 is a functional block diagram of the controller 600 according to an embodiment of the present inventive concept.

Referring to FIG. 4, the controller 600 may include an impedance control module (e.g., an impedance control circuit) 610 and a direct current (DC) power supply 620.

The impedance control module 610 may control the impedance of each of the inner electrode 300 and the outer electrodes 400. The inner electrode 300, the first outer electrode 410, and the second outer electrode 420 may be respectively connected to independent impedance control modules of the impedance control module 610. Accordingly, the impedance of the inner electrode 300, the first outer electrode 410, and the second outer electrode 420 may be independently controlled.

The impedance control module 610 may include an inductor and a vacuum variable capacitor (VVC). The impedance control module 610 may include a number of VVCs that is equal to the total number of electrodes including the inner electrode 300 and the outer electrodes 400.

When the impedance control module 610 independently controls the impedance of the inner electrode 300, the first outer electrode 410, and the second outer electrode 420, the thickness uniformity and film properties (k) may be increased during CVD.

The DC power supply 620 may supply power to the inner electrode 300 and the outer electrodes 400. The inner electrode 300, the first outer electrode 410, and the second outer electrode 420 may be respectively connected to independent DC power supplies of the DC power supply 620. Accordingly, different powers may be supplied to the inner electrode 300, the first outer electrode 410, and the second outer electrode 420. For example, the power supplied to each of the inner electrode 300, the first outer electrode 410, and the second outer electrode 420 may be independently controlled.

The impedance control module 610 and the DC power supply 620 may each be connected to the inner electrode 300 and the outer electrodes 400 through a radio frequency (RF) filter board. For example, the impedance control module 610 and the DC power supply 620 may be connected in parallel to the RF filter board, and the RF filter board may be connected to the inner electrode 300, the first outer electrode 410, and the second outer electrode 420 respectively through the inner conductive wire 310, the first outer conductive wire 418, and the second outer conductive wire 428.

The controller 600 may control different chucking forces that are to be generated in the inner electrode 300, the first outer electrode 410, and the second outer electrode 420 through the impedance control module 610 and the DC power supply 620.

The temperature controller 700 may be located outside the chuck plate 100 and the shaft 200. The temperature controller 700 may control the temperature of the heater electrode 500.

According to an embodiment of the present inventive concept, the temperature controller 700 may include an outer temperature controller 710 and an inner temperature controller 720. The outer temperature controller 710 may control the temperature of the outer coil 520 through a conductive wire, and the inner temperature controller 720 may control the temperature of the inner coil 520 through a conductive wire. According to an embodiment of the present inventive concept, the inner temperature controller 710 and the outer temperature controller 720 may respectively control the outer coil 520 and the inner coil 510 to different temperatures from each other. According to an embodiment of the present inventive concept, the temperature controller 700 may control the temperature of an electrode such that CVD is carried out at a high temperature of about 600 degrees Celsius or higher.

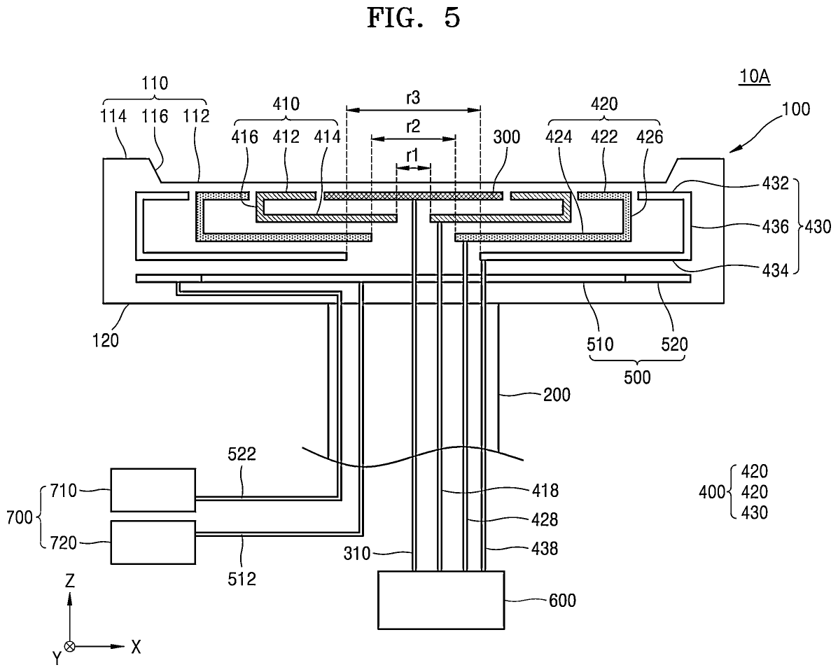

FIG. 5 is a cross-sectional view of an electrostatic chuck apparatus 10A according to an embodiment of the present inventive concept. To the extent that various elements are not described in detail with respect to FIG. 5, it may be assumed that these elements are at least similar to corresponding elements described in detail elsewhere within the instant application. The electrostatic chuck apparatus 10A of FIG. 5 is described with focus on the differences from the electrostatic chuck apparatus 10 of FIGS. 1 to 4.

Referring to FIG. 5, the electrostatic chuck apparatus 10A may further include a third outer electrode 430.

The third outer electrode 430 may include a third top portion 432, a third bottom portion 434, and a third side portion 436. The shape of the third outer electrode 430 may be similar to the shape of each of the first outer electrode 410 and the second outer electrode 420.

The third top portion 432 may have a planar annular shape and may be located outside the second top portion 422 in the radial direction of the chuck plate 100. For example, the third top portion 432 may be adjacent to the second top portion 422. The third top portion 432 may be located in the chuck plate 100 to be adjacent to the top surface 110 of the chuck plate 100 in the vertical direction (the Z direction). The inner diameter of the third top portion 432 may be greater than the outer diameter of the second top portion 422. The third top portion 432 may be concentric to the second top portion 422 and separated from the second top portion 422 in the radial direction of the chuck plate 100.

The third bottom portion 434 may have a planar annular shape and may be located inside the chuck plate 100. The third bottom portion 434 may be separated from the third top portion 432 in the vertical direction (the Z direction). According to an embodiment of the present inventive concept, the outer diameter of the third bottom portion 434 may be the same as the outer diameter of the third top portion 432, and the inner diameter of the third bottom portion 434 may be less than the inner diameter of the third top portion 432.

The third side portion 436 may have a cylindrical shape and may connect the third top portion 432 to the third bottom portion 434. In other words, the top outer circumference of the third side portion 436 may be connected to the outer circumference of the third top portion 432, and the bottom outer circumference of the third side portion 436 may be connected to the outer circumference of the third bottom portion 434.

A third outer conductive wire 438 may be connected to the third bottom portion 434. The third outer conductive wire 438 may connect the third outer electrode 430 to the controller 600. The third outer conductive wire 438 may penetrate through the chuck plate 100 and extend in the inner space of the shaft 200. The third outer conductive wire 438 may be connected to the third outer electrode 430 through an electrode terminal.

The third outer electrode 430 may be arranged such that the central axis of the third outer electrode 430 coincides with the central axes of the inner electrode 300, the first outer electrode 410, and the second outer electrode 420. The third outer electrode 430 may be arranged to surround the side and the bottom of the second outer electrode 420.

The third top portion 432 of the third outer electrode 430 may be at substantially the same vertical level as the inner electrode 300, the first top portion 412 of the first outer electrode 410, and the second top portion 422 of the second outer electrode 420. The third top portion 432 of the third outer electrode 430, which is located outermost, with respect to the inner electrode 300, the first top portion 412 and the second top portion 422, in the radial direction of the chuck plate 100, may at least partially overlap the wafer supporting surface 112 in the vertical direction (the Z direction).

The third bottom portion 434 of the third outer electrode 430 may be below the second bottom portion 424 of the second outer electrode 420. An inner diameter r3 of the third bottom portion 434 may be greater than the inner diameter r2 of the second bottom portion 424.

The third outer conductive wire 438, which connects the third outer electrode 430 to the controller 600, may be connected to a side of the third bottom portion 434. The third outer electrode 430 may be connected to the impedance control module 610 and the DC power supply 620 through the third outer conductive wire 438. The impedance of the third outer electrode 430 may be controlled independently of the impedance of each of the inner electrode 300, the first outer electrode 410, and the second outer electrode 420. Power may be independently supplied to the third outer electrode 430, the inner electrode 300, the first outer electrode 410, and the second outer electrode 420.

Although it is illustrated in FIG. 5 that the electrostatic chuck apparatus 10A includes first outer electrode 410, the second outer electrode 420, and the third outer electrode 430, embodiments of the present inventive concept are not limited thereto. The electrostatic chuck apparatus 10A may include more external electrodes.

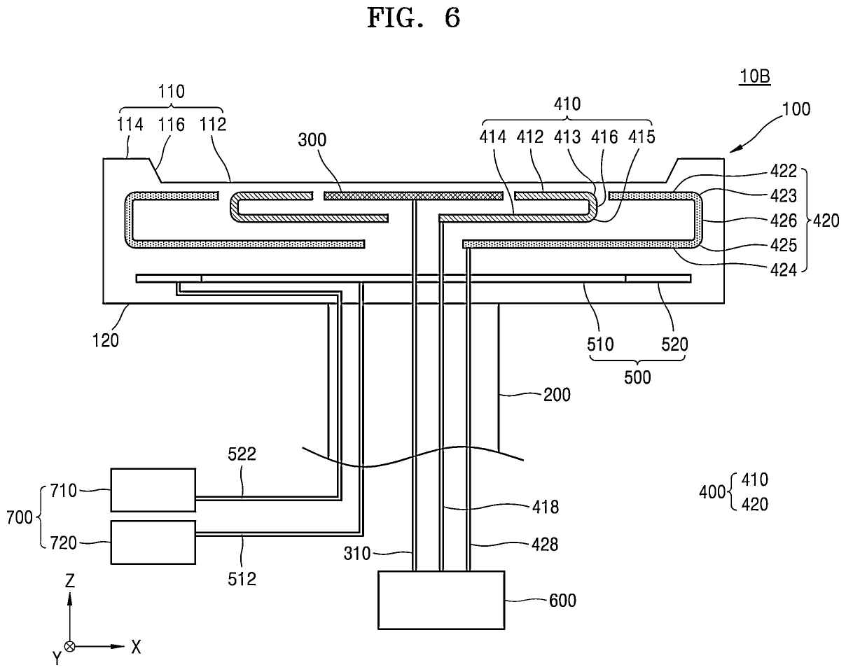

FIG. 6 is a cross-sectional view of an electrostatic chuck apparatus 10B according to an embodiment of the present inventive concept. To the extent that various elements are not described in detail with respect to FIG. 6, it may be assumed that these elements are at least similar to corresponding elements described in detail elsewhere within the instant application. The electrostatic chuck apparatus 10B of FIG. 6 is described with focus on the differences from the electrostatic chuck apparatus 10 of FIGS. 1 to 4 and the electrostatic chuck apparatus 10A of FIG. 5.

Referring to FIG. 6, each of the outer electrodes 400 of the electrostatic chuck apparatus 10B may include an upper round portion, which connects an upper portion to a side portion, and a lower round portion, which connects the side portion to a lower portion.

According to an embodiment of the present inventive concept, the first outer electrode 410 may include the first top portion 412, a first upper round portion 413, the first bottom portion 414, a first lower round portion 415, and the first side portion 416.

Compared to the first outer electrode 410 of the electrostatic chuck apparatus 10 of FIG. 2, which has a right angle at a portion where each of the first top portion 412 and the first bottom portion 414 meets the first side portion 416, the first outer electrode 410 of the electrostatic chuck apparatus 10B of FIG. 6 may further include the first upper round portion 413 connecting the top end of the first side portion 416 to the first top portion 412 in a round shape. The first outer electrode 410 of the electrostatic chuck apparatus 10B may further include the first lower round portion 415 connecting the bottom end of the first side portion 416 to the first bottom portion 414 in a round shape. For example, the first outer electrode 410 may include rounded corners.

In an embodiment of the present inventive concept, the top outer circumference of the first side portion 416 may be connected to the outer circumference of the first top portion 412 through the first upper round portion 413, and the bottom outer circumference of the first side portion 416 may be connected to the outer circumference of the first bottom portion 414 through the first lower round portion 415.

Similarly, the second outer electrode 420 may include the second top portion 422, a second upper round portion 423, the second bottom portion 424, a second lower round portion 425, and the second side portion 426.

Compared to the second outer electrode 420 of the electrostatic chuck apparatus 10 of FIG. 2, the second outer electrode 420 of the electrostatic chuck apparatus 10B of FIG. 6 may further include the second upper round portion 423 connecting the top end of the second side portion 426 to the second top portion 422 in a round shape. The second outer electrode 420 of the electrostatic chuck apparatus 10B may further include the second lower round portion 425 connecting the bottom end of the second side portion 426 to the second bottom portion 424 in a round shape. For example, the second outer electrode 420 may include rounded corners.

In an embodiment of the present inventive concept, the top outer circumference of the second side portion 426 may be connected to the outer circumference of the second top portion 422 through the second upper round portion 423 and the bottom outer circumference of the second side portion 426 may be connected to the outer circumference of the second bottom portion 424 through the second lower round portion 425.

Similar to the electrostatic chuck apparatus 10 of FIG. 2, in the electrostatic chuck apparatus 10B of FIG. 6, the first top portion 412 of the first outer electrode 410 may be at substantially the same vertical level as the inner electrode 300 and located outside the inner electrode 300 in the radial direction of the chuck plate 100, and the second top portion 422 of the second outer electrode 420 may be at substantially the same vertical level as the inner electrode 300 and located outside the first top portion 412 of the first outer electrode 410 in the radial direction of the chuck plate 100.

According to an embodiment of the present inventive concept, the inner electrode 300 having a disc shape and the first top portion 412 having a planar annular shape may be overlapped by the wafer supporting surface 112 in the vertical direction (the Z direction). For example, the inner electrode 300 having a disc shape and the first top portion 412 having a planar annular shape may be entirely overlapped by the wafer supporting surface 112 in the vertical direction (the Z direction). The second top portion 422, which has a planar annular shape and is located outermost, with respect to the inner electrode 300 and the first outer electrode 410, in the radial direction of the chuck plate 100, may at least partially overlap the wafer supporting surface 112 in the vertical direction (the Z direction).

For example, each of the first outer electrode 410 and the second outer electrode 420 may be integrally formed by bending a single mesh electrode. The first upper round portion 413 may be formed by bending in a round shape between the first side portion 416 and the first top portion 412. The first lower round portion 415 may be formed by bending in a round shape between the first side portion 416 and the first bottom portion 414. The second upper round portion 423 may be formed by bending in a round shape between the second side portion 426 and the second top portion 422. The second lower round portion 425 may be formed by bending in a round shape between the second side portion 426 and the second bottom portion 424.

According to an embodiment of the present inventive concept, the first outer electrode 410 may be formed by bonding the first top portion 412, the first bottom portion 414, and the first side portion 416 to each other. When the first top portion 412 having a planar annular shape is bonded to the first side portion 416 having a cylindrical shape, a portion where the first top portion 412 meets the first side portion 416 may be rounded, thereby forming the first upper round portion 413. When the first bottom portion 414 having a planar annular shape is bonded to the first side portion 416 having a cylindrical shape, a portion where the first bottom portion 414 meets the first side portion 416 may be rounded, thereby forming the first lower round portion 415.

Similarly, according to an embodiment of the present inventive concept, the second outer electrode 420 may be formed by bonding the second top portion 422, the second bottom portion 424, and the second side portion 426 to each other. When the second top portion 422 having a planar annular shape is bonded to the second side portion 426 having a cylindrical shape, a portion where the second top portion 422 meets the second side portion 426 may be rounded, thereby forming the second upper round portion 423. When the second bottom portion 424 having a planar annular shape is bonded to the second side portion 426 having a cylindrical shape, a portion where the second bottom portion 424 meets the second side portion 426 may be rounded, thereby forming the second lower round portion 425.

Although it is illustrated in FIG. 6 that the electrostatic chuck apparatus 10B includes first outer electrode 410 and the second outer electrode 420, embodiments of the present inventive concept are not limited thereto. The electrostatic chuck apparatus 10B may include more external electrodes.

According to an embodiment of the present inventive concept, the electrostatic chuck apparatus 10 may include a plurality of outer electrodes 400 each having a 3D shape. An outer conductive wire connecting each of the outer electrodes 400 to the controller 600 may extend inside the chuck plate 100 in one direction (the Z direction) without a bent portion and may continuously extend in the shaft 200. The chuck plate 100 including therein an outer conductive wire arranged in one direction without a bent portion may reduce a risk of internal cracking and ensure sinterability thereof. Accordingly, the electrostatic chuck apparatus 10 may be suitable to be used in CVD at a high temperature of about 600 degrees Celsius or higher.

Moreover, the electrostatic chuck apparatus 10 may include the inner electrode 300 and the outer electrodes 400 and may independently control power that is applied to the inner electrode 300 and the outer electrodes 400 and the impedance of the inner electrode 300 and the outer electrodes 400. Accordingly, the electrostatic chuck apparatus 10 may provide a chucking force that is locally necessary to control wafer warpage during high-temperature CVD and may increase the uniformity of film quality during the CVD.

While the present inventive concept has been described with reference to embodiments thereof, it will be understood by those of ordinary skill in the art that various changes in form and details may be made thereto without departing from the spirit and scope of the present inventive concept.

What is claimed is:

1. An electrostatic chuck apparatus comprising:
a chuck plate configured to support a wafer;
a shaft extending from a bottom surface of the chuck plate in a vertical direction and configured to support the chuck plate;
an inner electrode disposed inside the chuck plate and having a disc shape in a central portion of the chuck plate; and
a plurality of outer electrodes disposed inside the chuck plate and adjacent to the inner electrode in a radial direction of the chuck plate,
wherein the plurality of outer electrodes include a first outer electrode including:
a first side portion having a cylindrical shape and extending in the vertical direction;
a first top portion having a planar annular shape and connected to an upper end of the first side portion; and
a first bottom portion having a planar annular shape and connected to a lower end of the first side portion.

2. The electrostatic chuck apparatus of claim 1, wherein
the plurality of outer electrodes further include a second outer electrode including:
a second side portion having a cylindrical shape and extending in the vertical direction;
a second top portion having a planar annular shape and connected to an upper end of the second side portion; and
a second bottom portion having a planar annular shape and connected to a lower end of the second side portion,
wherein the first top portion of the first outer electrode is adjacent to the inner electrode in the radial direction of the chuck plate at substantially a same vertical level as the inner electrode, and
wherein the second top portion of the second outer electrode is adjacent to the first top portion in the radial direction of the chuck plate at substantially the same vertical level as the inner electrode.

3. The electrostatic chuck apparatus of claim 2, wherein
the top surface of the chuck plate includes a wafer supporting surface on which the wafer is mounted and a circumferential surface around the wafer supporting surface,
the inner electrode and the first top portion of the first outer electrode overlap the wafer supporting surface in the vertical direction, and
the second top portion of the second outer electrode at least partially overlaps the wafer supporting surface in the vertical direction.

4. The electrostatic chuck apparatus of claim 2, wherein
an inner diameter of the first bottom portion of the first outer electrode is less than an inner diameter of the first top portion of the first outer electrode, and
an inner diameter of the second bottom portion of the second outer electrode is less than an inner diameter of the second top portion of the second outer electrode.

5. The electrostatic chuck apparatus of claim 2, wherein
the second bottom portion of the second outer electrode is disposed below the first bottom portion of the first outer electrode, and
an inner diameter of the second bottom portion of the second outer electrode is greater than an inner diameter of the first bottom portion of the first outer electrode.

6. The electrostatic chuck apparatus of claim 2, wherein,
in the first outer electrode, an upper outer circumference of the first side portion is connected to an outer circumference of the first top portion, and a lower outer circumference of the first side portion is connected to an outer circumference of the first bottom portion, and
in the second outer electrode, an upper outer circumference of the second side portion is connected to an outer circumference of the second top portion, and a lower outer circumference of the second side portion is connected to an outer circumference of the second bottom portion.

7. The electrostatic chuck apparatus of claim 2, further comprising:
an inner conductive wire extending in the shaft and connected to the inner electrode;
a first outer conductive wire extending in the shaft and connected to the first bottom portion of the first outer electrode; and
a second outer conductive wire extending in the shaft and connected to the second bottom portion of the second outer electrode.

8. The electrostatic chuck apparatus of claim 7, wherein
the inner conductive wire, the first outer conductive wire, and the second outer conductive wire are each connected to a direct current (DC) power supply.

9. The electrostatic chuck apparatus of claim 8, wherein
the inner electrode, the first outer electrode, and the second outer electrode are supplied with different power from each other by the DC power supply.

10. The electrostatic chuck apparatus of claim 7, wherein
the inner conductive wire, the first outer conductive wire, and the second outer conductive wire are each connected to an impedance control module.

11. The electrostatic chuck apparatus of claim 1, further comprising a heater electrode disposed below the inner electrode and the plurality of outer electrodes.

12. The electrostatic chuck apparatus of claim 11, wherein
the heater electrode includes:
an inner coil in the central portion of the chuck plate and connected to an inner temperature controller; and
an outer coil disposed adjacent to the inner coil in the radial direction of the chuck plate and connected to an outer temperature controller.

13. The electrostatic chuck apparatus of claim 1, wherein
the first top portion, the first bottom portion, and the first side portion of the first outer electrode are integrally formed together.

14. The electrostatic chuck apparatus of claim 1, wherein
the first outer electrode is formed by bonding the first top portion to the upper end of the first side portion and bonding the first bottom portion to the lower end of the first side portion.

15. The electrostatic chuck apparatus of claim 3, wherein
the plurality of outer electrodes further include a third outer electrode including:
a third side portion having a cylindrical shape and extending in the vertical direction;
a third top portion having a planar annular shape and connected to an upper end of the third side portion; and
a third bottom portion having a planar annular shape and connected to a lower end of the third side portion,
wherein the third top portion of the third outer electrode is adjacent to the second top portion of the second outer electrode in the radial direction of the chuck plate at substantially the same vertical level as the inner electrode, and
wherein the third top portion of the third outer electrode at least partially overlaps the wafer supporting surface in the vertical direction.

16. An electrostatic chuck apparatus comprising:
a chuck plate including a top surface that includes a wafer supporting surface and a circumferential surface, wherein a wafer is mounted on the wafer supporting surface, and wherein the circumferential surface is around an outer edge of the wafer supporting surface and forms a step with the wafer supporting surface;
a shaft extending from a bottom surface of the chuck plate in a vertical direction and configured to support the chuck plate;
an inner electrode disposed inside the chuck plate and having a disc shape in a central portion of the chuck plate;
a first outer electrode disposed inside the chuck plate and including a first side portion, a first top portion, and a first bottom portion, wherein the first side portion has a cylindrical shape and extends in the vertical direction, wherein the first top portion has a planar annular shape that is connected to an upper end of the first side portion and that is arranged adjacent to the inner electrode in a radial direction of the chuck plate, wherein the first top portion is disposed at substantially a same vertical level as the inner electrode and overlaps the wafer supporting surface in the vertical direction, wherein the first bottom portion has a planar annular shape that is connected to a lower end of the first side portion, and wherein the first bottom portion has an inner diameter that is less than an inner diameter of the first top portion;
a second outer electrode disposed inside the chuck plate and including a second side portion, a second top portion, and a second bottom portion, wherein the second side portion has a cylindrical shape and extends in the vertical direction, wherein the second top portion has a planar annular shape that is connected to an upper end of the second side portion and that is arranged adjacent to the first top portion of the first outer electrode in the radial direction of the chuck plate, wherein the second top portion is disposed at substantially the same vertical level as the inner electrode and at least partially overlaps the wafer supporting surface in the vertical direction, wherein the second bottom portion has a planar annular shape that is connected to a lower end of the second side portion, and wherein the second bottom portion has an inner diameter that is less than an inner diameter of the second top portion;
an inner conductive wire connected to the inner electrode;
a first outer conductive wire connected to the first bottom portion of the first outer electrode;
a second outer conductive wire connected to the second bottom portion of the second outer electrode; and
a heater electrode overlapping the inner electrode, the first outer electrode, and the second outer electrode,
wherein the second bottom portion of the second outer electrode is disposed below the first bottom portion of the first outer electrode, wherein an inner diameter of the second bottom portion of the second outer electrode is greater than an inner diameter of the first bottom portion of the first outer electrode, and
wherein the inner conductive wire, the first outer conductive wire, and the second outer conductive wire are each connected to a direct current (DC) power supply and an impedance control module.

17. An electrostatic chuck apparatus comprising:
a chuck plate configured to support a wafer;
a shaft extending from a bottom surface of the chuck plate in a vertical direction and configured to support the chuck plate;
an inner electrode disposed inside the chuck plate and having a disc shape in a central portion of the chuck plate; and
a plurality of outer electrodes disposed inside the chuck plate and adjacent to the inner electrode in a radial direction of the chuck plate,
wherein the plurality of outer electrodes includes a first outer electrode including:
a first side portion having a cylindrical shape and extending in the vertical direction;
a first top portion having a planar annular shape;
a first upper round portion connecting the first top portion to a top end of the first side portion;
a first bottom portion having a planar annular shape; and
a first lower round portion connecting the first bottom portion to a bottom end of the first side portion.

18. The electrostatic chuck apparatus of claim 17, wherein
the plurality of outer electrodes further includes a second outer electrode including:
a second side portion having a cylindrical shape and extending in the vertical direction;
a second top portion having a planar annular shape;
a second upper round portion connecting the second top portion to a top end of the second side portion;
a second bottom portion having a planar annular shape; and
a second lower round portion connecting the second bottom portion to a bottom end of the second side portion,
wherein the first top portion of the first outer electrode is adjacent to the inner electrode in the radial direction of the chuck plate at substantially a same vertical level as the inner electrode, and
wherein the second top portion of the second outer electrode is adjacent to the first top portion in the radial direction of the chuck plate at substantially the same vertical level as the inner electrode.

19. The electrostatic chuck apparatus of claim 18, wherein
the top surface of the chuck plate includes a wafer supporting surface with the wafer mounted thereon and a circumferential surface around an outer edge of the wafer supporting surface,
the inner electrode and the first top portion of the first outer electrode are entirely overlapped by the wafer supporting surface in the vertical direction, and
the second top portion of the second outer electrode at least partially overlaps the wafer supporting surface in the vertical direction.

20. The electrostatic chuck apparatus of claim 18, wherein
in the first outer electrode, a top outer circumference of the first side portion is connected to an outer circumference of the first top portion through the first upper round portion, and a bottom outer circumference of the first side portion is connected to an outer circumference of the first bottom portion through the first lower round portion, and
in the second outer electrode, a top outer circumference of the second side portion is connected to an outer circumference of the second top portion through the second upper round portion, and a bottom outer circumference of the second side portion is connected to an outer circumference of the second bottom portion through the second lower round portion.
